(19) United States
(12) Patent Application Publication
(10) Pub. No.: US 2025/0031498 A1
(43) Pub. Date: Jan. 23, 2025

(54) Display Panel and Display Apparatus Including Same

(71) Applicant: LG Display Co., Ltd., Seoul (KR)

(72) Inventors: Yong Hoon Lee, Paju-si (KR); Woo Sung Kim, Paju-si (KR); Jong Soo Han, Paju-si (KR); Sang Hak Shin, Paju-si (KR); Dong Kyu Kim, Paju-si (KR); Hyoung Sun Park, Paju-si (KR); Hyun Seok Na, Paju-si (KR); Hyun Chyol Shin, Paju-si (KR); Seong Soo Cho, Paju-si (KR)

(21) Appl. No.: 18/676,007

(22) Filed: May 28, 2024

(30) Foreign Application Priority Data
Jul. 18, 2023 (KR) 10-2023-0093225

(51) Int. Cl. H01L 33/58; H01L 25/075; H01L 25/16; H01L 27/12; H01L 33/38; H01L 33/62

(52) U.S. Cl. CPC H01L 33/58; H01L 25/0753; H01L 25/167; H01L 27/124; H01L 33/38; H01L 33/62

(57) ABSTRACT

A display panel and a display apparatus including the display panel are presented herein. A display panel according to one or more embodiments includes a substrate; an insulating layer on the substrate; a bank pattern on the insulating layer; a first electrode on the bank pattern; a contact electrode on the insulating layer, the contact electrode spaced apart from the bank pattern; a light-emitting element on the first electrode; a first optical layer surrounding the light-emitting element, the first optical layer comprising an organic insulating material including metal particles; a second optical layer on the contact electrode; and a third optical layer on the first optical layer.

### CROSS-REFERENCE TO RELATED APPLICATION

This application claims the priority from Republic of Korea Patent Application No. 10-2023-0093225, filed on Jul. 18, 2023, which is hereby incorporated by reference in its entirety.

### BACKGROUND

### Field

The present disclosure relates to a display panel and a display apparatus including the same.

### Description of Related Art

As flat display apparatuses, liquid crystal display apparatuses and organic light-emitting display apparatuses, etc. are used. The organic light-emitting display apparatuses have the advantage of improved light emission efficiency, fast response speed, wide viewing angle, and the like compared to the liquid crystal display apparatuses. However, since the organic light-emitting display apparatuses have low light emission efficiency and are vulnerable to moisture due to organic materials included therein, reliability and lifespan thereof may be reduced.

Recently, micro light-emitting diode display apparatuses being inorganic light-emitting display apparatuses have been proposed. The micro light-emitting diode display apparatuses produce images by disposing an inorganic light-emitting diode having a size, for example, of 100 μm or less in each pixel.

### SUMMARY

The present disclosure provides a display panel that is capable of reducing or preventing the diffusion of fine metal particles and a display apparatus including the same.

The problems or limitations to be solved or addressed by the present disclosure are not limited to those mentioned above, and other problems or limitations not mentioned will be clearly understood by those skilled in the art from the following description.

According to one or more embodiments of the present disclosure, a display panel may include a substrate; an insulating layer on the substrate; a bank pattern on the insulating layer; a first electrode on the bank pattern; a contact electrode on the insulating layer, the contact electrode spaced apart from the bank pattern; a light-emitting element on the first electrode; a first optical layer surrounding the light-emitting element, the first optical layer comprising an organic insulating material including metal particles; a second optical layer on the contact electrode; and a third optical layer on the first optical layer.

According to one or more embodiments of the present disclosure, a display apparatus may include a display panel including a plurality of pixels and a pixel driving circuit that drive the plurality of pixels, the display panel may include a substrate; an insulating layer on the substrate; a bank pattern on the insulating layer; a first electrode on the bank pattern; a contact electrode on the insulating layer, the contact electrode spaced apart from the bank pattern; a light-emitting element on the first electrode; a first optical layer surrounding the light-emitting element, the first optical layer comprising an organic insulating material including metal particles; a second optical layer on the contact electrode; and a third optical layer on the first optical layer.

According to one or more embodiments of the present disclosure, a display apparatus may include a substrate; an insulating layer on the substrate; a first anode on the insulating layer; a first light emitting element on the first anode; a second anode on the insulating layer; a second light emitting element on the second anode; a first optical layer between and surrounding the first light emitting element and the second light emitting element, the first optical layer comprising an organic insulating material including a plurality of particles; a third optical layer on an upper surface of the first optical layer, the third optical layer surrounding the first light emitting element and the second light emitting element; a cathode on the first light emitting element, the second light emitting element, and the third optical layer; and a pixel driving circuit connected to the first anode and the second anode, the pixel driving circuit configured to supply one or more voltages to at least one of the first anode and the second anode.

According to one or more embodiments of the present disclosure, a first optical layer including fine metal particles surrounds a micro light-emitting diode, and a third optical layer including no fine metal particles is on the first optical layer, so that it is possible to reduce or prevent the fine metal particles of the first optical layer from being diffused.

According to one or more embodiments of the present disclosure, since the third optical layer reduce or prevents the fine metal particles of the first optical layer from being diffused, the flatness of the third optical layer where a cathode electrode is formed is increased, so that it is possible to reduce or prevent the cathode electrode from being damaged.

According to one or more embodiments of the present disclosure, since the flatness of the second optical layer is increased, the cathode electrode may be prevented from being damaged, and since an increase in the resistance of the cathode electrode is suppressed, the lighting rate of the micro light-emitting diode may be improved.

According to one or more embodiments of the present disclosure, since an increase in the resistance of the cathode electrode is suppressed and thus the lighting rate of the micro light-emitting diode is improved, power consumption may be reduced, so that low-power driving is possible.

The effects of the present disclosure are not limited to the above-mentioned effects, and other effects that are not mentioned will be apparently understood by those skilled in the art from the following description and the appended claims.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

The above and other objects, features and advantages of the present disclosure will become more apparent to those of ordinary skill in the art by describing embodiments thereof in detail with reference to the attached drawings, in which:

FIG. 1 is a diagram illustrating a display device according to one or more embodiments of the present disclosure;

FIG. 2 is an enlarged view of an area A of FIG. 1 according to one or more embodiments of the present disclosure;

FIG. 3 is a diagram illustrating a partial area of a pixel according to one or more embodiments of the present disclosure;

FIG. 4 is a cross-sectional view taken along line I-I′ in FIG. 3 according to one or more embodiments of the present disclosure;

FIG. 5 is a cross-sectional view taken along line II-II′ in FIG. 3 according to one or more embodiments of the present disclosure;

FIG. 6 is a cross-sectional view taken along line III-III′ in FIG. 3 according to one or more embodiments of the present disclosure;

FIG. 7 is a cross-sectional view illustrating an example in which a main light emitting element and a sub-light emitting element are electrically connected to a pixel driving circuit according to one or more embodiments of the present disclosure;

FIG. 8 is a diagram illustrating a display device according to one or more embodiments of the present disclosure;

FIG. 9 is a cross-sectional view taken along line IV-IV′ in FIG. 8 according to one or more embodiments of the present disclosure;

FIG. 10 is a view illustrating an image to a light-emitting element covered by a first optical layer according to one or more embodiments of the present disclosure;

FIG. 11 is a view illustrating an image in which a third optical layer is covered on a first optical layer according to one or more embodiments of the present disclosure;

FIG. 12 is a view illustrating an image in which no third optical layer is present on a first optical layer according to one or more embodiments of the present disclosure;

FIG. 13 is a view illustrating a method for manufacturing a display apparatus according to one or more embodiments of the present disclosure;

FIGS. 14A to 14G are views for explaining a method for manufacturing a display apparatus illustrated in FIG. 13 according to one or more embodiments of the present disclosure;

FIG. 15 is a view for explaining a method for manufacturing a display apparatus according to one or more embodiments of the present disclosure;

FIGS. 16A to 16H are views for explaining a method for manufacturing a display apparatus illustrated in FIG. 15 according to one or more embodiments of the present disclosure;

FIG. 17 is a view for explaining a method for manufacturing a display apparatus according to one or more embodiments of the present disclosure;

FIGS. 18A to 18G are views for explaining a method for manufacturing a display apparatus illustrated in FIG. 17 according to one or more embodiments of the present disclosure; and

FIG. 19 is a view illustrating the results of simulating light output efficiency of an example and a comparative example according to one or more embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the present specification. Further, in describing the present disclosure, detailed descriptions of known related technologies may be omitted to avoid unnecessarily obscuring the subject matter of the present disclosure.

The terms such as “comprising,” “including,” and “having” used herein are generally intended to allow other components to be added unless the terms are used with the term “only.” Any references to singular may include plural unless expressly stated otherwise.

Components are interpreted to include an ordinary error range even if not expressly

stated. Any implementation described herein as an “example” is not necessarily to be construed as preferred or advantageous over other implementations.

When a positional or interconnected relationship is described between two components, such as “on top of,” “above,” “below,” “next to,” “connect or couple with,” “crossing,” “intersecting,” or the like, one or more other components may be interposed between them, unless “immediately” or “directly” is used.

The terms, such as “below,” “lower,” “above,” “upper” and the like, may be used herein to describe a relationship between item(s) as illustrated in the drawings. It will be understood that the terms are spatially relative and based on the orientation depicted in the drawings.

When a temporal antecedent relationship is described, such as “after”, “following”, “next to”, “before”, or the like, it may not be continuous on a time base unless “immediately” or “directly” is used.

The terms “first,” “second,” “A,” “B,” “(a),” and “(b),” and the like may be used to distinguish elements from each other, but the functions or structures of the components are not limited by ordinal numbers or component names in front of the components.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The following embodiments can be partially or entirely bonded to or combined with each other and can be linked and operated in technically various ways. The embodiments can be carried out independently of or in association with each other.

Hereinafter, various embodiments of the present disclosure will be described in detail with reference to the accompanying drawings.

In this specification, a first optical layer including fine metal particles is formed to surround a light-emitting element, and a third optical layer including no fine metal particles is formed on the first optical layer, thereby reducing or preventing the fine metal particles of the first optical layer from being diffused by doubling coating of the first optical layer and the third optical layer.

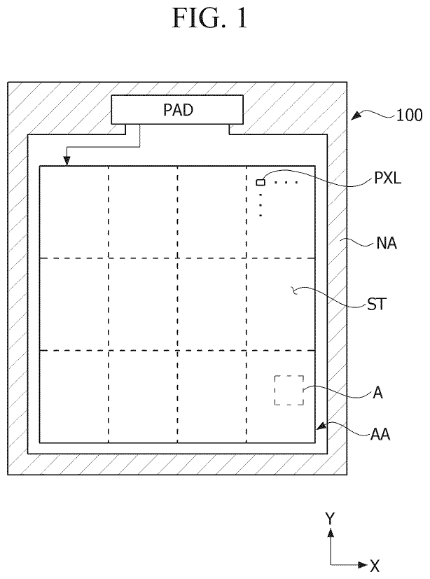

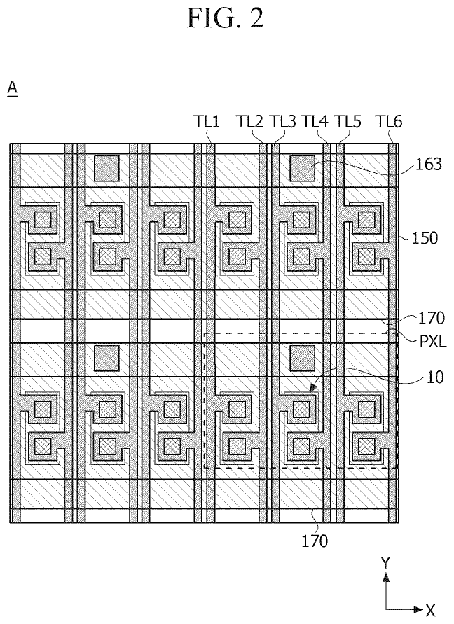

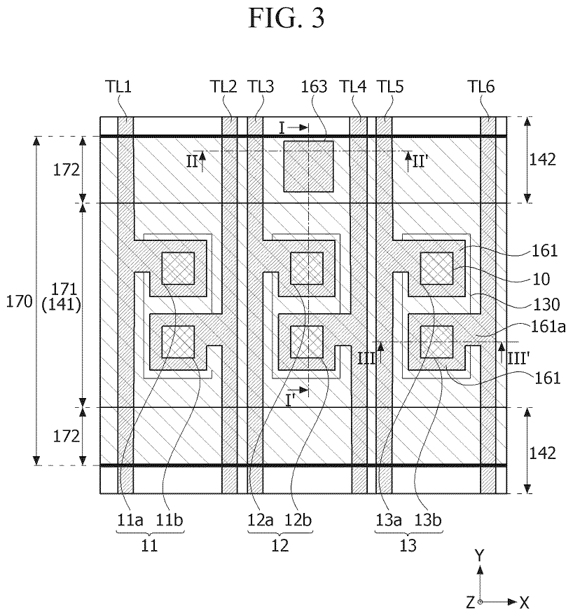

FIG. 1 is a diagram illustrating a display device according to one or more embodiments of the present disclosure; FIG. 2 is an enlarged view of an area A of FIG. 1 according to one or more embodiments of the present disclosure; FIG. 3 is a diagram illustrating a partial area of a pixel according to one or more embodiments of the present disclosure.

Referring to FIGS. 1 and 2, a display device according to one or more embodiments of the present disclosure includes a display panel 100 that visually reproduces an input image. The display panel 100 may include a display area AA in which an image is displayed and a non-display area NA in which the image is not displayed. In the non-display area NA, various wire and driving circuits may be mounted and/or a pad part PAD to which integrated circuits, printed circuits, etc. are connected may be disposed.

A plurality of light emitting elements 10 disposed in the display area AA to form pixels PXL may be inorganic light emitting elements (e.g., inorganic light emitting elements). The inorganic light emitting elements may be grown on a silicon wafer and then attached to the display panel through a transfer process, without being limited thereto.

The transfer process of the light emitting element 10 may be performed for each pre-divided area. In FIG. 1, the display area AA is divided into nine transfer areas STs, but the size or number of divisions of the transfer areas is not limited thereto. As an example, the display area AA may be divided into two or more transfer areas STs. As an example, the display area AA may be divided into more than nine transfer areas STs. The transfer process may be performed sequentially or simultaneously on at least some of the first to ninth transfer areas STs. In the transfer area ST, blue, green, and red light emitting elements 10 may be sequentially transferred, respectively, without being limited thereto. As an example, the arrangement of the blue, green, and red light emitting elements 10 may be variously changed. As an example, light emitting elements of other colors may be also possible.

In the non-display area NA, as an example, a data driving circuit or a gate driving circuit may be disposed, and wires for supplying control signals to control these driving circuits may be disposed, without being limited thereto. Here, the control signals may include various timing signals including a clock signal, an input data enable signal, and a synchronization signal, and may be received through the pad portion PAD. As an example, the data driving circuit or the gate driving circuit may not be disposed in the non-display area NA. As an example, the data driving circuit or the gate driving circuit may be separately disposed in a separate panel and connected to the display panel 100 (e.g., the pad portion PAD), for example, in a tape automated bonding (TAB) method, a chip on glass (COG) method, a chip on panel (COP) method, or a chip on film (COF) method, without being limited thereto.

The pixels PXL may be driven by a pixel driving circuit. The pixel driving circuit may receive a driving voltage, an image signal (digital signal), a synchronization signal synchronized with the image signal, etc., and output an anode voltage and a cathode voltage of the light emitting element 10 to drive a plurality of pixels. The driving voltage may be a high potential voltage (EVDD). The cathode voltage may be a low potential voltage (EVSS) (e.g., commonly) applied to the pixels. The anode voltage may be a voltage corresponding to the pixel data value of the image signal. The pixel driving circuit may be disposed in the non-display area NA or a lower portion of the display area AA.

Each of the pixels PXL may include a plurality of sub-pixels each having a different color. For example, each of the plurality of pixels may include a red sub-pixel in which the light emitting element 10 that emits light in a red wavelength is disposed, a green sub-pixel in which the light emitting element 10 that emits light in a green wavelength is disposed, and a blue sub-pixel in which the light emitting element 10 that emits light in a blue wavelength is disposed. The plurality of pixels may further include white pixels, however embodiments of the present disclosure are not limited thereto. As an example, sub-pixels emitting light of other colors such as magenta, cyan, or yellow may be alternatively or additionally included.

Referring to FIGS. 2 and 3, the plurality of pixels PXL may be sequentially arranged in a first direction (X-axis direction) and a second direction (Y-axis direction), without being limited thereto. As an example, the plurality of pixels PXL may be sequentially arranged in any direction between the first direction and the second direction. As an example, within each of the pixels of the display area AA, a plurality of sub-pixels of the same color may be arranged. For example, each of the plurality of pixels may include a first red sub-pixel in which a first-first light emitting element 11a that emits light in a red wavelength is disposed, a second red sub-pixel in which a first-second light emitting element 11b that emits light in a red wavelength is disposed, a first green sub-pixel in which a second-first light emitting element 12a emitting light in a green wavelength is disposed, a second green sub-pixel in which a second-second light emitting element 12b emitting light in a green wavelength is disposed, a first blue sub-pixel in which a third-first light emitting element 13a emitting light in a blue wavelength is disposed, and/or a second blue sub-pixel in which a third-second light emitting element 13b emitting light in a blue wavelength is disposed. As an example, the first-first light emitting element 11a, the second-first light emitting element 12a, and the third-first light emitting element 13a may be interpreted as main light emitting elements. As an example, the first-second light emitting element 11b, the second-second light emitting element 12b, and the third-second light emitting element 13b may be interpreted as sub-light emitting elements, however embodiments of the present disclosure are not limited thereto. As an example, each of the plurality of pixels may include one or more red sub-pixels, one or more green sub-pixels, and one or more blue sub-pixels. As an example, in each of the plurality of pixels, the number of the red sub-pixels, the number of the green sub-pixels, and the number of the blue sub-pixels may be the same as or different from each other.

As an example, one pixel includes one or more sub-pixels of the same color, or one sub-pixel includes one or more light emitting elements, and if one sub-pixel or one light emitting element becomes defective, the luminance of another sub-pixel or another light emitting element of the same color may be increased to adjust the luminance of the pixel or the sub-pixel. However, it is not necessarily limited to thereto, one pixel may include one sub-pixels of the same color and/or one sub-pixel may include only one light emitting element.

Each of a plurality of first electrodes 161 may be disposed in a lower portion of the light emitting element 10 and may be selectively connected to corresponding one of a plurality of signal wirings TL1 to TL6 by extension portions 161a. A high potential voltage may be applied to the pixel driving circuit through the signal wirings TL1 to TL6. The first electrode 161 and corresponding one of the signal wirings TL1 to TL6 may be formed as an integrated electrode pattern in an electrode patterning process.

As an example, the first signal wiring TL1 may be connected to an anode electrode of the first red sub-pixel, and the second signal wiring TL2 may be connected to an anode electrode of the second red sub-pixel. The third signal wiring TL3 may be connected to an anode electrode of the first green sub-pixel, and the fourth signal wiring TL4 may be connected to an anode electrode of the second green sub-pixel. The fifth signal wiring TL5 may be connected to an anode electrode of the first blue sub-pixel, and the sixth signal wiring TL6 may be connected to an anode electrode of the second blue sub-pixel. If one pixel includes only one sub-pixel of the same color, or one sub-pixel includes only one light emitting element, the number of signal wirings TL may be reduced by half.

A second electrode 170 may be a cathode electrode that is arranged in each row to apply a cathode voltage to the light emitting element 10 continuously arranged in the first direction (X-axis direction). The plurality of second electrodes 170 may be arranged to be spaced apart from each other in the second direction (Y-axis direction). The plurality of second electrodes 170 may receive the cathode voltage through a contact electrode 163. Each of the plurality of second electrodes 170 may be electrically connected to the contact electrode 163. However, it is not necessarily limited thereto, and the second electrode 170 may include one electrode layer instead of being divided into a plurality of electrodes to function as a common electrode. As another example, the second electrode 170 may be divided into a plurality of electrodes arranged in each column and spaced apart from each other in the first direction, or may be divided in other directions.

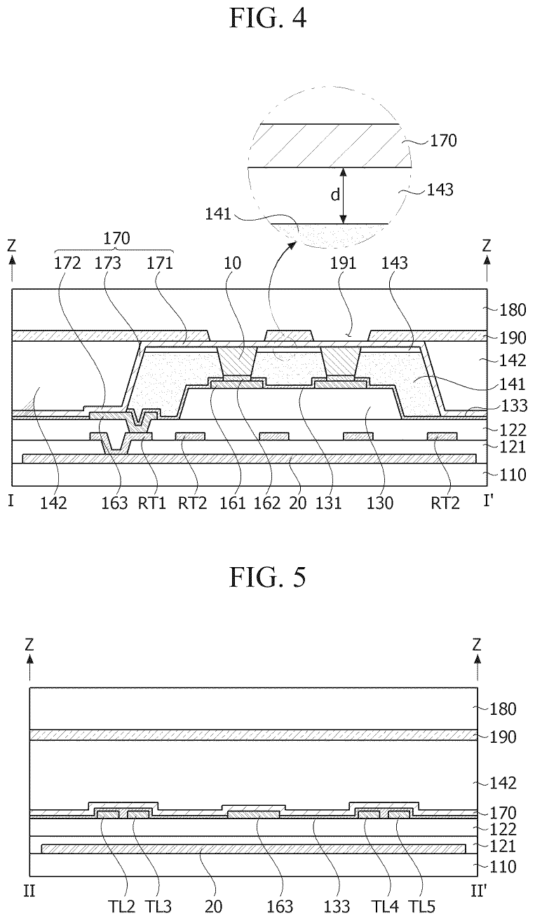

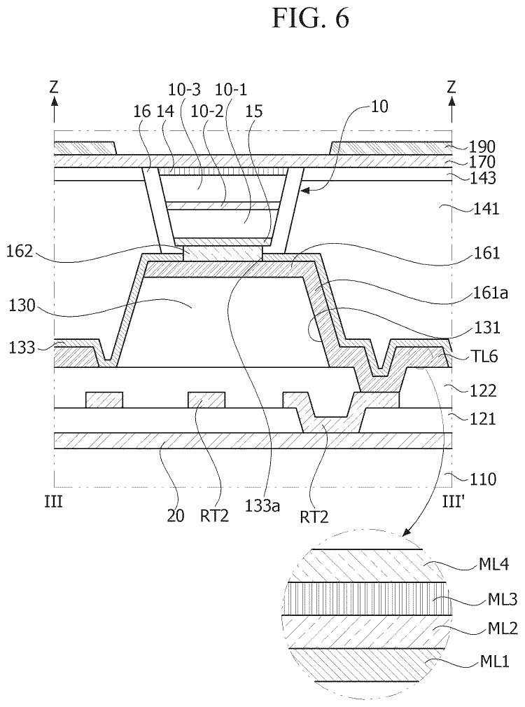

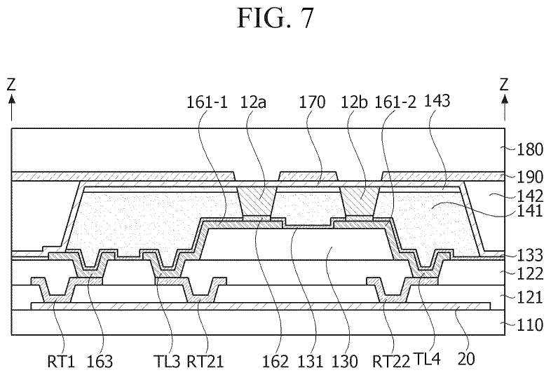

FIG. 4 is a cross-sectional view taken along line I-I′ in FIG. 3 according to one or more embodiments of the present disclosure. FIG. 5 is a cross-sectional view taken along line II-II′ in FIG. 3 according to one or more embodiments of the present disclosure. FIG. 6 is a cross-sectional view taken along line III-III′ in FIG. 3 according to one or more embodiments of the present disclosure. FIG. 7 is a cross-sectional view showing an example in which two light emitting elements are connected to a pixel driving circuit according to one or more embodiments of the present disclosure.

Referring to FIGS. 3 to 5, a display device according to one or more embodiments of the present disclosure includes a plurality of first electrodes 161 and a contact electrode 163 disposed on a substrate 110, a plurality of light emitting elements 10 disposed on a plurality of first electrodes 161, a first optical layer 141 disposed between the plurality of light emitting elements 10, and a second electrode 170 disposed on the plurality of light emitting elements 10.

The substrate 110 may be made of plastic with flexibility. For example, the substrate 110 may be made of a single-layer or multi-layer substrate of a material selected from polyimide, polyethylene terephthalate, polyethylene naphthalate, polycarbonate, polyethersulfone, polyarylate, polysulfone, and cyclic-olefin copolymer, but is not limited thereto. For example, the substrate 110 may be a ceramic substrate or a glass substrate, however, embodiments of the present disclosure are not limited thereto. As an example, the substrate 110 may be a rigid substrate made of a rigid material.

A pixel driving circuit 20 may be disposed in the display area AA on the substrate 110. The pixel driving circuit 20 may include a plurality of thin film transistors using an amorphous silicon semiconductor, a polycrystalline silicon semiconductor, an oxide semiconductor, an organic semiconductor, a compound semiconductor, or any other semiconductors.

The pixel driving circuit 20 may include at least one driving thin film transistor, at least one switching thin film transistor, and at least one storage capacitor. When the pixel driving circuit 20 includes a plurality of thin film transistors, it may be formed on the substrate 110 by a thin film transistor (TFT) manufacturing process. In one or more embodiments, the pixel driving circuit 20 may be a collective term for a plurality of thin film transistors electrically connected to the light emitting element 10.

The pixel driving circuit 20 may be a driving driver manufactured using a metal-oxide-silicon field effect transistor (MOSFET) manufacturing process on a single crystal semiconductor substrate 110, without being limited thereto. The driving driver may include a plurality of pixel driving circuits to drive a plurality of sub-pixels. When the pixel driving circuit 20 is implemented as a driving driver, after an adhesive layer is disposed on the substrate 110, the driving driver may be mounted on the adhesive layer by a transfer process, without being limited thereto.

A buffer layer 121 covering the pixel driving circuit 20 may be disposed on the substrate

110. The buffer layer 121 may be made of an organic insulating material, for example, photosensitive photo acryl or photosensitive polyimide, but is not limited thereto.

The buffer layer 121 may be formed by stacking an inorganic insulating material, for example, silicon nitride (SiNx) or silicon oxide (SiO₂) in multiple layers, may be formed by stacking an organic insulating material in multiple layers, or may be formed by stacking an organic insulating material and an inorganic insulating material in multiple layers.

An insulating layer 122 may be disposed on the buffer layer 121. The insulating layer 122 may be made of an organic insulating material, for example, photosensitive photo acryl or photosensitive polyimide, but is not limited thereto. Connection wirings RT1 and RT2 may be at least partially disposed on the buffer layer 121. The connection wirings RT1 and/or RT2 may be connected by the corresponding signal wirings TL1 to TL6 or may be connected to the signal wirings TL1 to TL6. The connection wirings RT1 and RT2 may include a plurality of wiring patterns disposed on different layers with one or more insulating layers interposed therebetween. The wiring patterns disposed on the different layers may be electrically connected via contact holes which passes through the insulating layers.

A plurality of bank patterns 130 may be disposed on the insulating layer 122. At least one light emitting element 10 may be disposed on each bank pattern 130. For example, a first light emitting element 11 may be disposed on a first bank pattern 130, a second light emitting element 12 may be disposed on a second bank pattern 130, and a third light emitting element 13 may be disposed on a third bank pattern 130.

The bank patterns 130 may be made of an organic insulating material, for example, photosensitive acryl or photosensitive polyimide, or an inorganic insulating material, but is not limited thereto. The bank pattern 130 may guide a position to which the light emitting element 10 is to be attached in the transfer process of the light emitting element 10. The bank pattern 130 may be omitted.

A solder pattern 162 may be disposed on the first electrode 161. The solder pattern 162 may be made of indium (In), tin (Sn), or an alloy thereof, but is not limited thereto. The solder pattern 162 may be an embodiment of a pad disposed on the first electrode 161.

The plurality of light emitting elements 10 may each be mounted on the solder pattern 162. One pixel may include light emitting elements 10 of three colors. The first light emitting element 11 may be a red light emitting element, the second light emitting element 12 may be a green light emitting element, and the third light emitting element 13 may be a blue light emitting element. As an example, two light emitting elements may be mounted in each sub-pixel.

A first optical layer 141 may cover the plurality of light emitting elements 10 and the bank pattern 130. Accordingly, the first optical layer 141 may cover a first area between the plurality of light emitting elements 10 and a second area between the plurality of bank patterns 130. The first optical layer 141 may extend in the first direction (X) and be spaced apart in the second direction (Y) to be separated between rows of pixels. As an example, the first optical layer 141 may cover an edge of the first electrode 161, without being limited thereto. The first electrode 161 may extend under the first optical layer 142 and may be connected to the pixel driving circuit 20 through the insulating layer 122.

As an example, the first optical layer 141 may include an organic insulating material in which fine metal particles such as titanium dioxide particles are dispersed, without being limited thereto. Light emitted from the plurality of light emitting elements 10 may be scattered by fine metal particles dispersed in the first optical layer 141 to be emitted externally, however embodiments of the present disclosure are not limited thereto. As an example, the first optical layer 141 may include an organic insulating material in which particles of other materials are dispersed. As an example, the first optical layer 141 may include an organic insulating material in which particles or fine metal particles of certain reflectivity are dispersed. As an example, the first optical layer 141 may include an organic insulating material in which fine metal oxide particles are dispersed. As an example, the first optical layer 141 may include an organic insulating material in which particles containing a metal element are dispersed.

The second electrode 170 may be disposed on the plurality of light emitting elements 10. The second electrode 170 may be commonly connected to the plurality of pixels PXL. The second electrode 170 may be an electrode through which light is transmitted. The second electrode 170 may be a transparent electrode material, for example, indium tin oxide (ITO) or indium zinc oxide (IZO), but is not necessarily limited thereto. As an example, the second electrode 170 may be a semi-transmissive metal material such as magnesium Mg, silver Ag, or alloys thereof.

The second electrode 170 may extend in the first direction (X-axis direction) and be spaced apart in the second direction (Y-axis direction). The second electrode 170 may include a first area 171 disposed on a top surface of the light emitting element 10 and a top surface of the first optical layer 141, a second area 172 in contact with the contact electrode 163 and electrically connected to the contact electrode 163, and a third area 173 disposed on a side of the first optical layer 141 and connecting the first area 171 and the second area 172.

On a plane, each of the plurality of second electrodes 170 may overlap the first optical layer 141, and the second area 172 may cover a plane outside the first optical layer 141. As an example, the second area 172 may cover a plane outside the first optical layer 141 in the second direction.

The second optical layer 142 may be an organic insulating material surrounding the first optical layer 141. The second optical layer 142 may be disposed on the insulating layer 122 together with the first optical layer 141. The second optical layer 142 may cover a portion of the second electrode 170. The first optical layer 141 and the second optical layer 142 may include the same material (e. g., siloxane). For example, the first optical layer 141 may be siloxane containing titanium oxide (TiOx), and the second optical layer 142 may be siloxane not containing titanium oxide (TiOx). However, it is not necessarily limited to thereto, and the first optical layer 141 and the second optical layer 142 may be formed of the same material or may be formed of different materials.

According to one or more embodiments, since the second area 172 of the second electrode 170 is connected to the contact electrode 163 in an overall flat state, excessive stress is not concentrated at the point of connection with the contact electrode 163. Therefore, it is possible to effectively reduce or prevent cracks from occurring in the second electrode 170.

The second optical layer 142 may cover the second area 172 and the third area 173 of the second electrode 170. The top surface of the second optical layer 142 and the top surface of the first area 171 of the second electrode 170 may be coplanar. In other words, the first optical layer 141 and the second optical layer 142 may function as planarization layers. As a result, a pattern of a black matrix 190 may be easily formed on the first optical layer 141 and the second optical layer 142 because there is no step on the surface where the black matrix 190 is formed. However, it is not necessarily limited to thereto, and the top surfaces of the second optical layer 142 and the second electrode 170 may have different heights. As an example, the pattern of a black matrix 190 may be omitted according to the design.

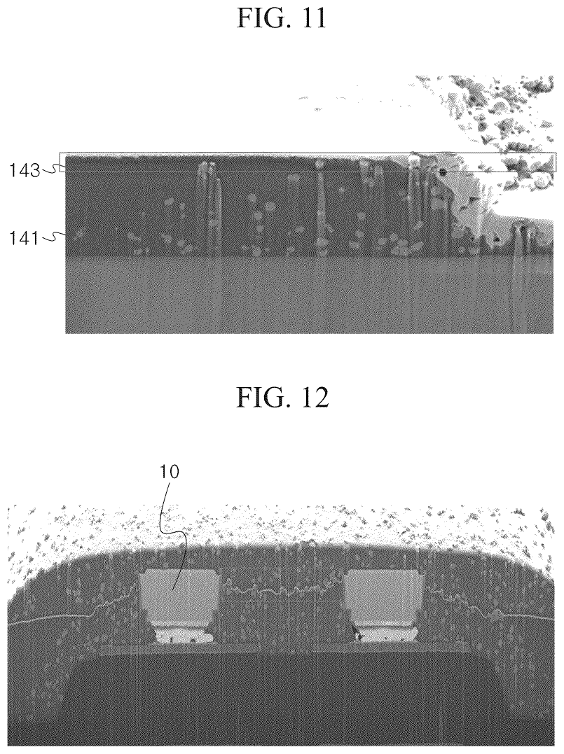

As an example, a third optical layer 143 may be an organic insulating material on the first optical layer 141. For example, the third optical layer 143 is on an upper surface of the first optical layer 141 and contacts the upper surface of the first optical layer 141. The third optical layer 143 may block the diffusion of the fine metal particles of the first optical layer 141. The fine metal particles of the first optical layer 141 may be diffused in the first optical layer 141 except at a top surface of the third optical layer 143. The third optical layer 143 may function as a shield for the second electrode 170. Without the third optical layer 143, the fine metal particles of the first optical layer 141 may diffuse towards the second electrode 170 thereby forming a rough upper surface of the first optical layer 141 which may damage the second electrode 170, as further described with respect to FIG. 10. However, with the third optical layer 143 between the first optical layer 141 and the second electrode 170, as further described with respect to FIGS. 11-12, the third optical layer 143 reduces the influence of the diffusion of the fine metal particles of the first optical layer 141 on the second electrode 170.

The third optical layer 143 may be formed so that a top surface of the third optical layer 143 is on the same line as or lower than top surfaces of the light-emitting elements 10. That is, the top surface of the third optical layer 143 is aligned (e.g., coplanar) with top surfaces of the light-emitting elements 10. The third optical layer 143 may also be formed on the first optical layer 141 to have a constant thickness. However, the embodiment is not necessarily limited thereto, and the thickness of the third optical layer 143 may be formed consistently or may be formed irregularly. As an example, the third optical layer 143 may be omitted according to the design.

For example, a thickness d of the third optical layer 143 may be set in a range of, for example, 1 μm to 2 μm, without being limited thereto.

In such a case, the second optical layer 142 and the third optical layer 143 may be made of the same organic insulating material. For example, the second optical layer 142 and the third optical layer 143 may be made of siloxane including no titanium oxide (TiOx). However, the embodiment is not necessarily limited thereto. As an example, the first optical layer 141, the second optical layer 142 and the third optical layer 143 may be made of the same organic insulating material except for the fine metal particles of the first optical layer 141. The third optical layer 143 may be made of an organic insulating material without any particles. The second optical layer 142 and the third optical layer 143 may include a same organic insulating material without any particles. As an example, at least one of the first optical layer 141, the second optical layer 142 and the third optical layer 143 may be made of a different material.

The black matrix 190 may include an opaque material. As an example, the black matrix 190 may include an organic insulating material to which black pigment is added, without being limited thereto. Beneath the black matrix 190, the second electrode 170 may be in contact with the contact electrode 163. A transmission hole 191 may be formed between the patterns of the black matrix 190, through which light emitted from the light emitting element 10 is externally emitted. By the black matrix 190, the problem of mixing of light emitted from neighboring light emitting elements 10 by the first optical layer 141 may be improved.

The cover layer 180 may be an organic insulating material for covering the black matrix 190 and the second electrode 170. In FIG. 3, the configuration of the black matrix 190 and the cover layer 180 is omitted.

The contact electrode 163 is electrically connected to the first connection wiring RT1 disposed on a lower portion thereof, and the first connection wiring RT1 may be connected to the pixel driving circuit 20. Accordingly, the second electrode 170 may be applied with a cathode voltage through the contact electrode 163. The first electrode 161 may be electrically connected to the second connection wiring RT2. This will be described later in more details.

Referring to FIG. 5, the contact electrode 163 and signal wirings TL1 to TL6 may be disposed on the same plane. The pixel driving circuit 20 may be disposed on a lower portion of the contact electrode 163 and the signal wirings TL1 to TL6. When the pixel driving circuit 20 is a driving driver, a plurality of driving drivers may be disposed in the display panel.

A passivation layer 133 may expose the contact electrode 163 so that the contact electrode 163 and the second electrode 170 are electrically connected. In addition, the passivation layer 133 may insulate the signal wirings TL2 to TL5 and the second electrode 170.

Referring to FIG. 6, a connection portion 161a of the first electrode 161 extends to one side surface 131 of the bank pattern 130 and is electrically connected to the connection wiring RT2 disposed on the insulating layer 122. As an example, the connection portion 161a is branched from the first electrode 161 in a direction crossing or vertical to a direction along which the light-emitting elements 10 are arranged on the bank pattern 130, without being limited thereto.

The first electrode 161, the connection portion 161a, the signal wiring TL, and/or the connection wirings RT1 and RT2 may include a single or multi-layer metal layer selected from titanium (Ti), molybdenum (Mo), and aluminum (Al), without being limited thereto. The first electrode 161, the connection portion 161a, the signal wiring TL and/or the connection wirings RT1 and RT2 may be formed in a multi-layer structure including a first layer ML1, a second layer ML2, a third layer ML3, and a fourth layer ML4, without being limited thereto. As an example, the first electrode 161, the connection portion 161a, the signal wiring TL and/or the connection wirings RT1 and RT2 may include at least one of a first layer ML1, a second layer ML2, a third layer ML3, and a fourth layer ML4 in common. As an example, the first electrode 161, the connection portion 161a, the signal wiring TL and/or the connection wirings RT1 and RT2 may include different number of layers or different materials.

The first layer ML1 and the third layer ML3 may include titanium (Ti) or molybdenum (Mo). The second layer ML2 may include aluminum (Al). The fourth layer ML4 may include a transparent conductive oxide layer such as indium tin oxide (ITO) or indium zinc oxide (IZO), which has good adhesion to the solder pattern 162, corrosion resistance, and acid resistance.

The first layer ML1, the second layer ML2, the third layer ML3, and the fourth layer ML4 may be sequentially deposited and then patterned by performing a photolithography process and an etching process, without being limited thereto.

The passivation layer 133 may be disposed on the first electrode 161 and the signal wiring TL and may include an opening hole 133a exposing the first electrode 161.

The light emitting element 10 may include a first conductive type semiconductor layer 10-1, an active layer 10-2 disposed on the first conductive type semiconductor layer 10-1, and a second conductive type semiconductor layer 10-3 disposed on the active layer 10-2. A first driving electrode 15 may be disposed on a lower portion of the first conductive type semiconductor layer 10-1, and a second driving electrode 14 may be disposed on an upper portion of the second conductive type semiconductor layer 10-3.

The light emitting element 10 may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, and the like.

The first conductivity type semiconductor layer 10-1 may be implemented as a compound semiconductor such as Group III-V, Group II-VI, etc., and may be doped with a first dopant, without being limited thereto. The first conductive type semiconductor layer 10-1 may be formed of any one or more of the semiconductor materials having a composition formula of Alₓ₁In_{y1}Ga_{(1-x1-y1)}N (0≤x1≤1, 0≤y1≤1, 0≤x1+y1≤1), InAlGaN, AlGaAs, GaP, GaAs, and AlGaInP, but is not limited thereto. When the first dopant is an n-type dopant such as Si, Ge, Sn, Se, Te, etc., the first conductive type semiconductor layer 10-1 may be an n-type semiconductor layer. However, when the first dopant is a p-type dopant, the first conductive type semiconductor layer 10-1 may be a p-type semiconductor layer.

The active layer 10-2 is a layer in which electrons (or holes) injected through the first conductive type semiconductor layer 10-1 meet holes (or electrons) injected through the second conductive type semiconductor layer 10-3. The active layer 10-2 may transition to lower energy levels as the electrons and holes are recombined and generate light that has a corresponding wavelength.

The active layer 10-2 may have any one of a single well structure, a multi-well structure, a single quantum well structure, a multi quantum well (MQW) structure, a quantum dot structure, or a quantum line structure, and the structure of the active layer 10-2 is not limited thereto. The active layer 10-2 may generate light in a visible light wavelength band or even an invisible light wavelength band. As an example, the active layer 10-2 may output light in any one of blue, green, and red wavelength bands, without being limited thereto.

The second conductive type semiconductor layer 10-3 may be disposed on the active layer 10-2. The second conductive type semiconductor layer 10-3 may be implemented as a compound semiconductor such as Group III-V, Group II-VI, etc., and the second conductive type semiconductor layer 10-3 may be doped with a second dopant, without being limited thereto. The second conductive type semiconductor layer 10-3 may be formed from semiconductor materials having a composition formula of Inₓ₂Al_{y2}Ga_{(1-x2-y2)}N (0≤x2≤1, 0≤y2≤1, 0≤x2+y2≤1) or materials selected from AlInN, AlGaAs, GaP, GaAs, GaAsP, and AlGaInP. When the second dopant is a p-type dopant such as Mg, Zn, Ca, Sr, Ba, etc., the second conductive type semiconductor layer 10-3 doped with the second dopant may be a p-type semiconductor layer. When the second dopant is an n-type dopant, the second conductive type semiconductor layer 10-3 may be an n-type semiconductor layer.

As an example, a reflective layer 16 may be disposed on a side surface and lower

portion of the light emitting element 10. The reflective layer 16 may have a structure in which a reflective material is dispersed in a resin layer, but is not necessarily limited to thereto. As an example, the reflective layer 16 may be manufactured as a reflector of various structures. Light emitted from the active layer 10-2 may be reflected upward by the reflective layer 16 to increase light extraction efficiency, however embodiments of the present disclosure are not limited thereto. As an example, the reflective layer 16 may be disposed on only a side surface of the light emitting element 10 in the first direction or in the second direction. As an example, the reflective layer 16 may be disposed on only a portion of the side surface of the light emitting element 10, or may be omitted according to the design.

Although the embodiment is described as a vertical structure in which the driving electrodes 14 and 15 are disposed on the upper and lower portion of the light-emitting structure, the light-emitting device may have a lateral structure or a flip chip structure other than the vertical structure.

Referring to FIG. 7, a main light emitting element 12a and sub-light emitting element 12b of the sub-pixel may be disposed on the bank pattern 130. The second light emitting element 12 will be illustratively described. A first-first electrode 161-1 connected to the main light emitting element 12a may extend to one side surface of the bank pattern 130 to be electrically connected to the second-first connection wiring RT21 disposed on a lower portion thereof. The second-first connection wiring RT21 may be formed at least partially on the buffer layer 121 and may be electrically connected to the pixel driving circuit 20 by passing through the buffer layer 121. The third signal wiring TL3 may be disposed on a portion of the second-first connection wiring RT21 and may electrically connect the second-first connection wiring RT21 to the first-first electrode 161-1. A first-second electrode 161-2 connected to the sub-light emitting element 12b may extend to the other side surface of the bank pattern 130 to be electrically connected to the second-second connection wiring RT22 disposed on a lower portion thereof. The second-second connection wiring RT21 may be formed at least partially on the buffer layer 121 and may be electrically connected to the pixel driving circuit 20 by passing through the buffer layer 121. The fourth signal wiring TL4 may be disposed on a portion of the second-second connection wiring RT22 and may electrically connect the second-second connection wiring RT22 to the first-second electrode 161-2.

The pixel driving circuit 20 may drive the main light emitting element 12a by applying a first anode voltage to the first-first electrode 161-1. The pixel driving circuit 20 may apply the first anode voltage to the first-first electrode 161-1 through the second-first connection wiring RT21 and the third signal wiring TL3. The pixel driving circuit 20 may drive the sub-light emitting element 12b by applying a second anode voltage to the first-second electrode 161-2. The pixel driving circuit 20 may apply the second anode voltage to the first-second electrode 161-2 through the second-second connection wiring RT22 and the fourth signal wiring TL4. The first connection wiring RT1 may be electrically connected to the pixel driving circuit 20 by passing through the buffer layer 121. The pixel driving circuit 20 may apply a cathode voltage to the main light emitting element 12a and the sub-light emitting element 12b through the first connection wiring RT1 and the second electrode 170.

The pixel driving circuit 20 may adjust luminance by driving only one of the main light emitting element 12a and the sub-light emitting element 12b, or may adjust luminance by simultaneously driving the main light emitting element 12a and the sub-light emitting element 12b. If the main light emitting element 12a is darkened, the luminance may be adjusted by driving only the sub-light emitting element 12b. As an example, the main light emitting element 12a and the sub-light emitting element 12b may be independently driven. As an example, the main light emitting element 12a and the sub-light emitting element 12b may be connected to different transistors in the pixel driving circuit 20. As an example, in a normal operation, the pixel driving circuit 20 may drive the main light emitting element 12a, or may drive both of the main light emitting element 12a and the sub-light emitting element 12b.

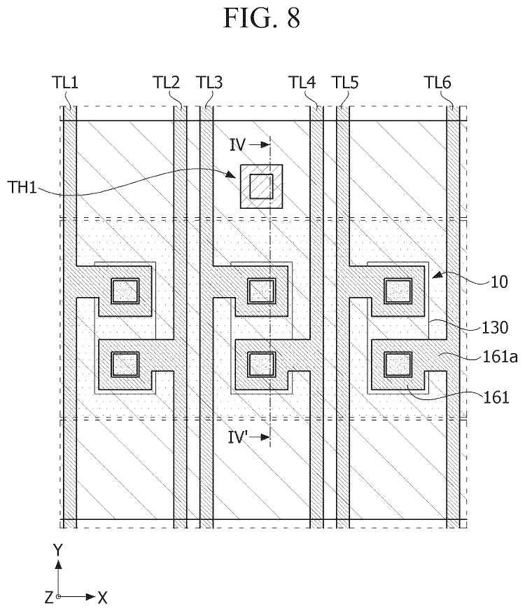

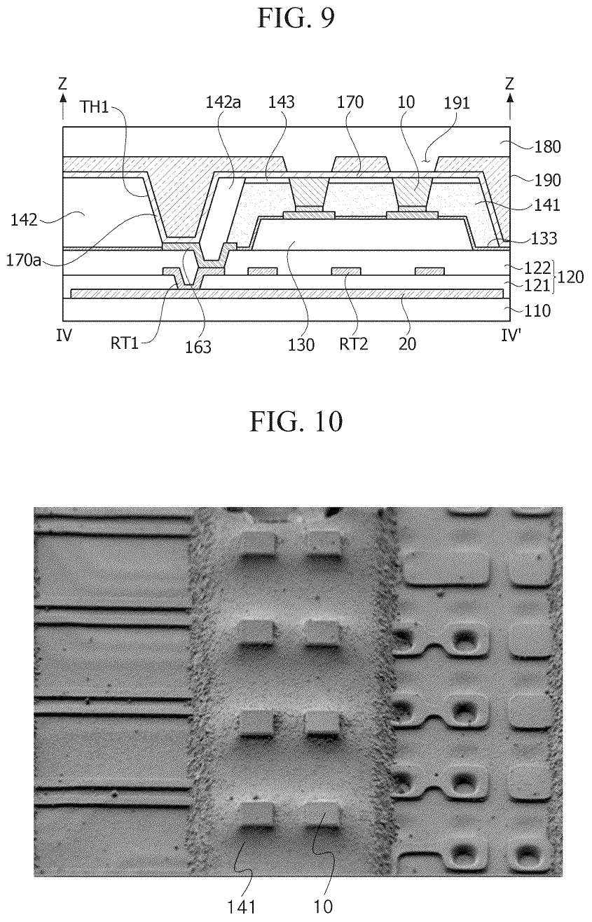

FIG. 8 is a diagram illustrating a display device according to one or more embodiments of the present disclosure. FIG. 9 is a cross-sectional view taken along line IV-IV′ in FIG. 8 according to one or more embodiments of the present disclosure.

Referring to FIGS. 8 and 9, the second electrode 170 may be electrically connected to the contact electrode 163 via a contact hole TH1 formed in the second optical layer 142. The second optical layer 142 may include the contact hole TH1 exposing a part of the contact electrode 163. The second electrode 170 may be inserted into the contact hole TH1 of the second optical layer 142 and may be in contact with an upper surface of the contact electrode 163. The contact hole TH1 may be formed in an outer area of the pixel. A first portion of the second electrode 170 may be on the second optical layer 142 and a second portion of the second electrode 170 may be connected to the contact electrode 163 through the contact hole TH1.

The reason for forming the third optical layer on the first optical layer in the present embodiment is as follows.

FIG. 10 is a view illustrating an image of a light-emitting element covered by a first optical layer according to one or more embodiments of the present disclosure. FIG. 11 is a view illustrating an image in which a third optical layer is covered on a first optical layer according to one or more embodiments of the present disclosure. FIG. 12 is a view illustrating an image in which no third optical layer is present on a first optical layer according to one or more embodiments of the present disclosure.

As shown in a scanning electron microscopy (SEM) image of FIG. 10, the light-emitting elements are covered by the first optical layer 141, but the top surfaces of the light-emitting elements are not covered by the first optical layer 141.

When the third optical layer is not formed on the first optical layer 141 as illustrated in FIG. 12 illustrating a comparative example, it can be seen that the fine metal particles of the first optical layer 141 are diffused and the top surface is not flat and is formed irregularly.

When the second electrode is formed on the first optical layer 141 having a rough top surface, damage to the second electrode may occur due to the diffusion of the fine metal particles of the first optical layer 141.

On the other hand, when the third optical layer 143 is formed on the first optical layer 141 as illustrated in FIG. 11 illustrating the embodiment, it can be seen that the top surface of the third optical layer 143 is not formed rough but is formed flat. The reason for this is that even though the fine metal particles of the first optical layer 141 are diffused, the fine metal particles are blocked by the third optical layer 143, so the top surface of the third optical layer 143 is formed flat.

Since the second electrode is formed on the third optical layer 143 instead of the first optical layer 141 having a rough top surface, damage to the second electrode may be reduced or prevented by the third optical layer 143.

Accordingly, in the one or more embodiments of the present disclosure, the third optical layer 143 is formed on the first optical layer 141.

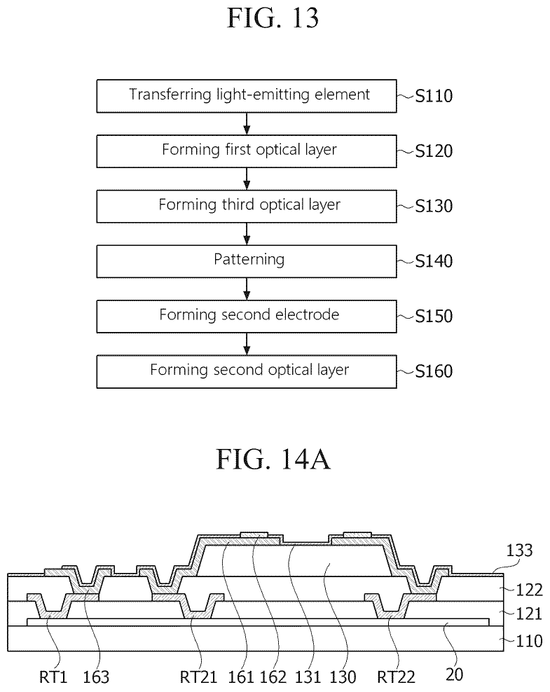

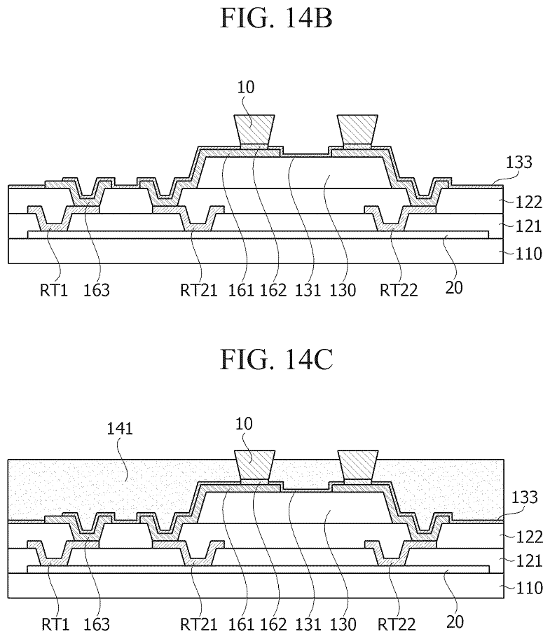

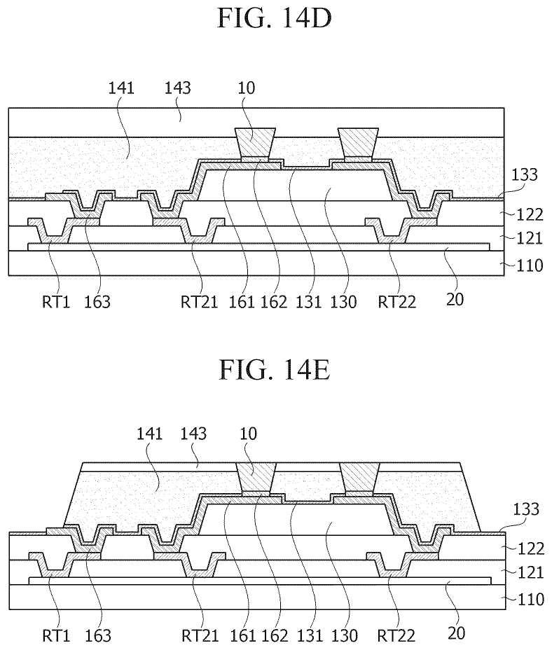

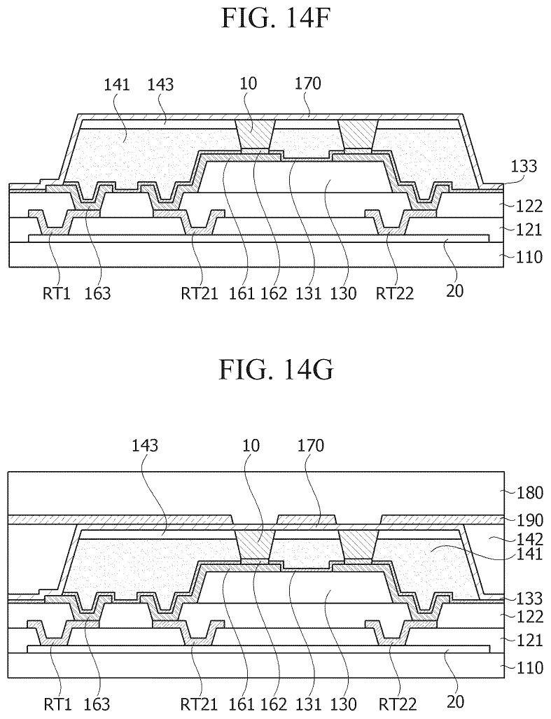

FIG. 13 is a view illustrating a method for manufacturing a display apparatus according to one or more embodiments of the present disclosure. FIGS. 14A to 14G are views for explaining a method for manufacturing a display apparatus illustrated in FIG. 13 according to one or more embodiments of the present disclosure. For convenience, a structure in which two micro light-emitting diodes are formed is described as an example, but the embodiment is not necessarily limited thereto and can be applied to various types of structures.

Referring to FIGS. 13, 14A, and 14B, the pixel driving circuit 20 may be formed on the substrate 110, and the buffer layer 121 may be formed on the pixel driving circuit 20. The pixel driving circuit 20 may receive a driving voltage, an image signal (digital signal), a synchronization signal synchronized with the image signal, or the like, and output an anode voltage and a cathode voltage of the light-emitting element 10 to drive a plurality of pixels. The pixel driving circuit 20 may be placed in a non-display area NA or below a display area AA.

Subsequently, the connection wires RT1 and RT2 may be formed on the buffer layer 121 and then the insulating layer 122 may be formed. The connection wires RT1 and RT2 may be electrically connected to the pixel driving circuit 20 by passing through the buffer layer 121. In order to drive each pixel, the number of connection wires RT1 and RT2 and the number of stacks of the connection wires RT1 and RT2 may be varied. Accordingly, the number of stacks of the connection wires RT1 and RT2 and the insulating layer 122 may be one or more layers.

The bank pattern 130 may be formed on the insulating layer 122 to select a location where the light-emitting element 10 is transferred. The bank pattern 130 may be made of an organic insulating material, for example, photosensitive acryl or photosensitive polyimide, but is not limited thereto. The bank pattern 130 may guide the location where the light-emitting element 10 is to be attached during the transfer process of the light-emitting element 10. However, the bank pattern 130 may be omitted.

An electrode material may be applied on the insulating layer 122 and the bank pattern 130 and then patterned to form a plurality of first electrodes 161 and contact electrodes 163. The first electrode 161 serves as an area where the light-emitting element 10 is disposed, and the contact electrode 163 serves as an area where the second electrode 170 is electrically connected. Subsequently, the passivation layer 133 may be formed on the plurality of first electrodes 161 and the contact electrodes 163 and the bank pattern 130 to expose at least a portion of the plurality of first electrodes 161 and the contact electrodes 163.

The solder pattern 162 may be formed on the exposed first electrode 161. The solder pattern 162 may be made of indium (In), tin (Sn), or an alloy thereof, but is not limited thereto. As an example, the solder pattern 162 may be omitted according to the design.

Subsequently, the plurality of light-emitting elements 10 may be transferred onto the solder pattern 162, respectively (S110). One pixel may include light-emitting elements 10 of three colors. A first light-emitting element may be a red light-emitting element, a second light-emitting element may be a green light-emitting element, and a third light-emitting element may be a blue light-emitting element. As an example, one or more (e.g., two) light-emitting elements may be mounted in each subpixel.

The transfer method is not particularly limited. That is, the light-emitting element 10 grown on the semiconductor growth substrate may be primarily transferred onto the transfer substrate and then secondarily transferred onto the panel substrate, or the light-emitting element 10 grown on the semiconductor growth substrate may be directly transferred onto the panel substrate.

Referring to FIGS. 13 and 14C to 14E, the first optical layer 141 may be entirely formed on the substrate 110 (S120), and the third optical layer 143 may be formed on the first optical layer 141 (S130) and then may be patterned so that the top surface of the light-emitting element 10 and the contact electrode 163 are exposed (S140). As an example, an upper surface of the first optical layer 141 may be lower than an upper surface of the light-emitting element 10, and a lower surface of the third optical layer 143 may be lower than the upper surface of the light-emitting element 10, without being limited thereto.

For example, the first optical layer 141 may be formed on the substrate 110 and the third optical layer 143 may be formed on the first optical layer 141 (S130), and then the first optical layer 141 and the third optical layer 143 may be cured at a predetermined temperature for a predetermined time. For example, the predetermined time may be set to 60 minutes and the predetermined temperature may be set to 170° C., but are not necessarily limited thereto.

Subsequently, some areas of the first optical layer 141 and the third optical layer 143 may be removed using exposure through a mask, but are not necessarily limited thereto. As an example, some areas of the first optical layer 141 and the third optical layer 143 may be removed to expose at least a portion of the contact electrodes 163, but are not necessarily limited thereto. The remaining portion of the first optical layer 141 may be partially removed to have a thickness sufficient to cover the light-emitting element 10 and the bank pattern 130. As an example, the remaining portion of the first optical layer 141 may be partially removed to expose an upper surface of the light-emitting element 10, but are not necessarily limited thereto. Accordingly, the first optical layer 141 may cover an area between the plurality of light-emitting elements 10 and the plurality of bank patterns 130. In such a case, the top surface of the light-emitting element 10 may be exposed at the top of the third optical layer 143.

The first optical layer 141 may include an organic insulating material in which fine metal oxide particles such as titanium dioxide particles are dispersed. The third optical layer 143 may include an organic insulating material. As an example, the third optical layer 143 may include an organic insulating material without the fine metal oxide particles.

Referring to FIGS. 13 and 14F, the second electrode 170 may be formed on the plurality of light-emitting elements 10 (S150). As an example, the second electrode 170 may be commonly connected to all pixels. As an example, the second electrode 170 may be commonly connected to at least some of the pixels. As an example, the second electrode 170 may be a thin metal electrode that transmits light. As an example, the second electrode 170 may be a transparent electrode material, for example, indium tin oxide (ITO), but is not necessarily limited thereto.

The second electrode 170 may be divided to be disposed in each row through patterning. The plurality of divided second electrodes 170 may be electrically connected to the contact electrodes 163, respectively.

Referring to FIGS. 13 and 14G, the second optical layer 142 may be formed to surround the first optical layer 141 (S160). In this process, the second optical layer 142 may cover a portion where the second electrode 170 is connected to the contact electrode 163.

The second optical layer 142 may be disposed on the insulating layer 122 together with the first optical layer 141. The first optical layer 141 and the second optical layer 142 may include the same material (for example, siloxane), but is not necessarily limited thereto. For example, the first optical layer 141 may be siloxane including titanium oxide (TiOₓ), and the second optical layer 142 may be siloxane including no titanium oxide (TiOₓ).

Subsequently, the black matrix 190 may be formed on the second electrode 170 and the second optical layer 142, and the cover layer 180 may be formed on the black matrix 190.

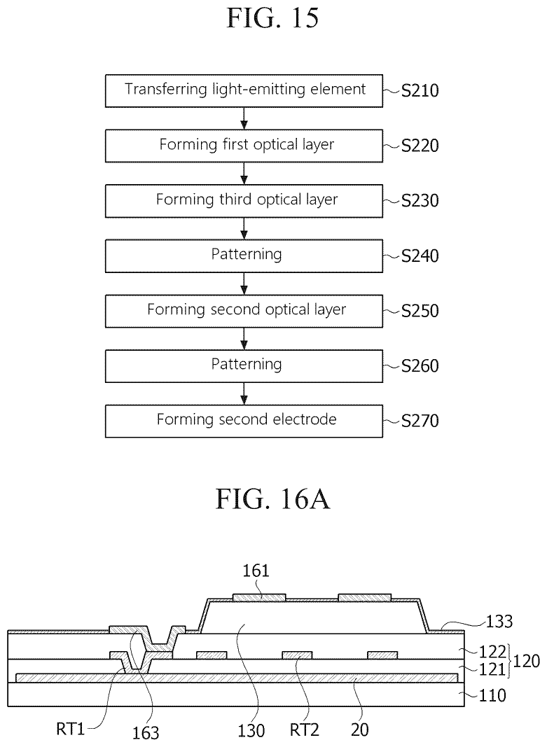

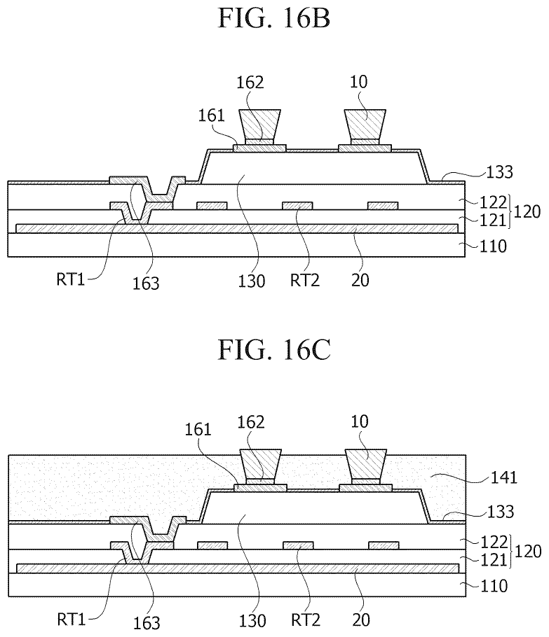

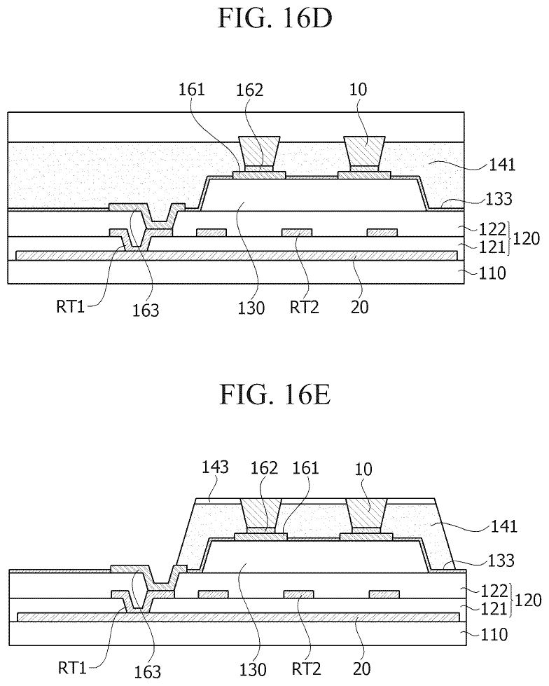

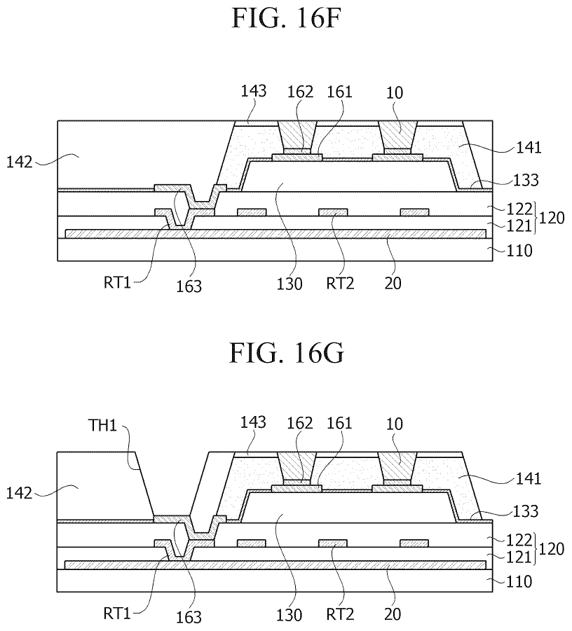

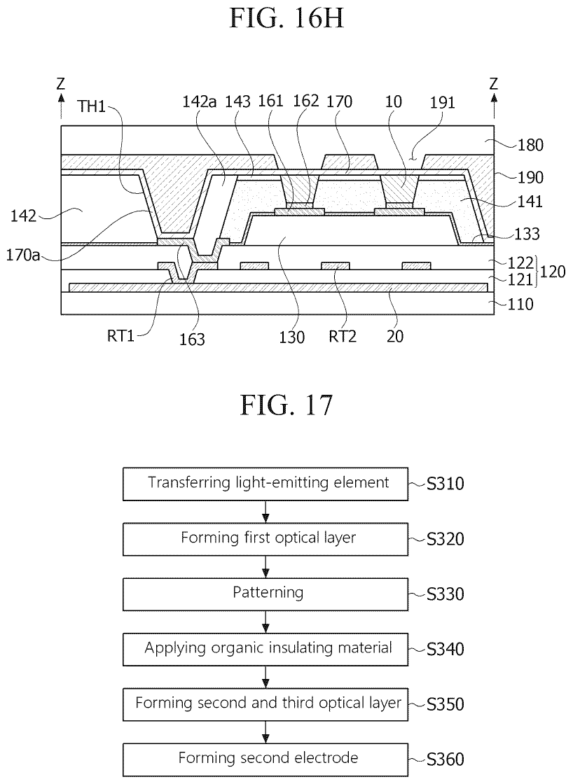

FIG. 15 is a view for explaining a method for manufacturing a display apparatus according to one or more embodiments of the present disclosure. FIGS. 16A to 16H are views for explaining a method for manufacturing a display apparatus illustrated in FIG. 15 according to one or more embodiments of the present disclosure.

Referring to FIGS. 15, 16A, and 16B, the pixel driving circuit 20 may be formed on the substrate 110, and the buffer layer 121 may be formed on the pixel driving circuit 20. Subsequently, the connection wires RT1 and RT2 may be formed on the buffer layer 121 and then the insulating layer 122 may be formed. The bank pattern 130 may be formed on the insulating layer 122 to select a location where the light-emitting element 10 is transferred. An electrode material may be applied on the insulating layer 122 and the bank pattern 130 and then patterned to form the plurality of first electrodes 161 and contact electrodes 163. The solder pattern 162 may be formed on the first electrode 161.

Subsequently, the plurality of light-emitting elements 10 may be transferred onto the solder pattern 162, respectively (S210). One pixel may include light-emitting elements 10 of three colors. A first light-emitting element may be a red light-emitting element, a second light-emitting element may be a green light-emitting element, and a third light-emitting element may be a blue light-emitting element. As an example, two or more light-emitting elements may be mounted in each subpixel.

Referring to FIGS. 15 and 16C to 16E, the first optical layer 141 may be entirely formed on the substrate 110 (S220), and the third optical layer 143 may be formed on the first optical layer 141 (S230) and then may be patterned so that the top surface of the light-emitting element 10 and the contact electrode 163 are exposed (S240).

Referring to FIGS. 15, 16F, and 16G, the second optical layer 142 may be formed in an area where the first and third optical layers 141 and 143 are removed (S250), and then may be patterned so that at least a portion of the contact electrode 163 is exposed (S260).

Referring to FIGS. 15 and 16H, the second electrode 170 may be formed on the plurality of light-emitting elements 10 (S270). The second electrode 170 may be commonly connected to all pixels or at least some of the pixels. As an example, the second electrode 170 may be a thin metal electrode that transmits light. As an example, the second electrode 170 may be a transparent electrode material, for example, indium tin oxide (ITO), but is not necessarily limited thereto.

Subsequently, the black matrix 190 may be formed on the second electrode 170 and the cover layer 180 may be formed on the black matrix 190.

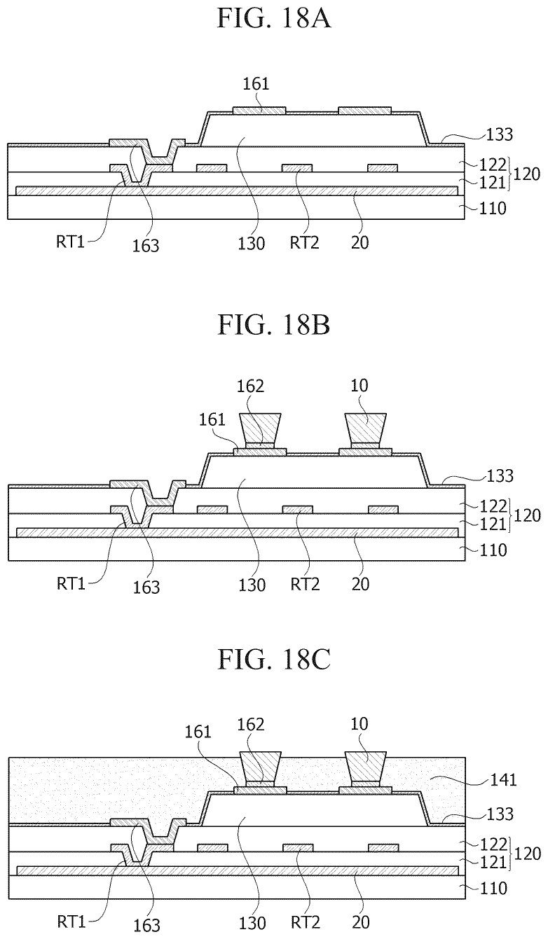

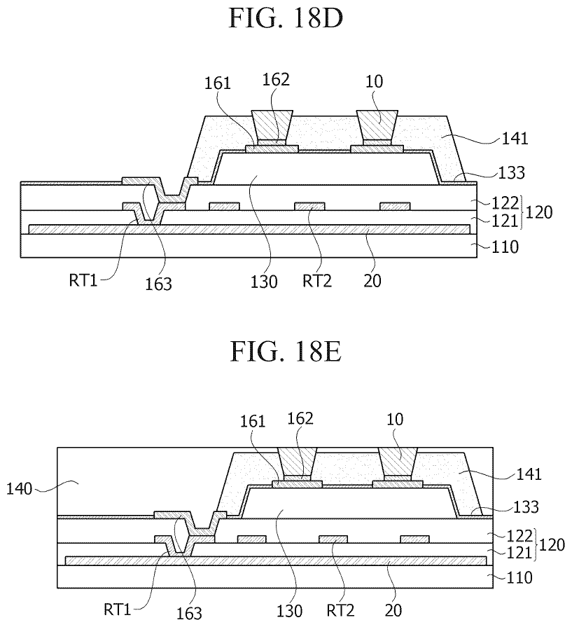

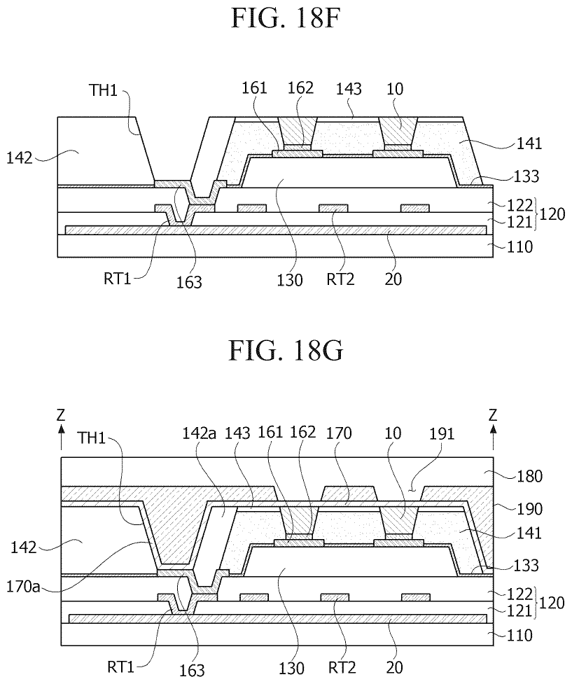

FIG. 17 is a view for explaining a method for manufacturing a display apparatus according to one or more embodiments of the present disclosure. FIGS. 18A to 18G are views for explaining a method for manufacturing a display apparatus illustrated in FIG. 17 according to one or more embodiments of the present disclosure.

Referring to FIGS. 17, 18A, and 18B, the pixel driving circuit 20 may be formed on the substrate 110, and the buffer layer 121 may be formed on the pixel driving circuit 20. Subsequently, the connection wires RT1 and RT2 may be formed on the buffer layer 121 and then the insulating layer 122 may be formed. The bank pattern 130 may be formed on the insulating layer 122 to select a location where the light-emitting element 10 is transferred. An electrode material may be applied on the insulating layer 122 and the bank pattern 130 and then patterned to form the plurality of first electrodes 161 and contact electrodes 163. The solder pattern 162 may be formed on the first electrode 161.

Subsequently, the plurality of light-emitting elements 10 may be transferred onto the solder pattern 162, respectively (S310). One pixel may include light-emitting elements 10 of three colors. A first light-emitting element may be a red light-emitting element, a second light-emitting element may be a green light-emitting element, and a third light-emitting element may be a blue light-emitting element. As an example, two or more light-emitting elements may be mounted in each subpixel.

Referring to FIGS. 17 and 18C to 18F, the first optical layer 141 may be entirely formed on the substrate 110 (S320), and then may be patterned (S330). For example, the first optical layer 141 may be patterned such that at least a portion of the contact electrode 163 and at least a portion of the passivation layer 133 is exposed without being limited thereto. Then, an organic insulating material 140 may be formed on the patterned first optical layer 141 (S340) and then may be patterned so that the top surface of the light-emitting element 10 and the contact electrode 163 are exposed, so that as a result of the patterning, the second optical layer 142 and the third optical layer 143 may be formed separately (S350).

For example, the third optical layer 143 may be formed by removing some areas of a coating layer in a first area through exposure using a half tone mask, and the second optical layer 142 having the contact hole TH1 may be formed by removing some areas of a coating layer in a second area through exposure using a full tone mask, without being limited thereto.

Subsequently, the second optical layer 142 and the third optical layer 143 may be cured at a predetermined temperature for a predetermined time. For example, the predetermined time may be set to 60 minutes and the predetermined temperature may be set to 170° C., but are not necessarily limited thereto.

Subsequently, a descum process may be performed to remove residues.

Referring to FIGS. 17 and 18G, the second electrode 170 may be formed on the plurality of light-emitting elements 10 (S360). The second electrode 170 may be commonly connected to all pixels or at least some of the pixels. The third optical layer 143 reduces or prevents the diffusion of the fine metal particles of the first optical layer 141, making it easy to form the second electrode 170.

Subsequently, the black matrix 190 may be formed on the second electrode 170 and the cover layer 180 may be formed on the black matrix 190.

In the one or more embodiments, since the materials of the second optical layer 142 and the third optical layer 143 are the same, the second optical layer 142 and the third optical layer 143 may be formed in one-time process and then formed using exposure through different masks. Using such a method has the advantage of reducing the manufacturing process and cost of the display apparatus.

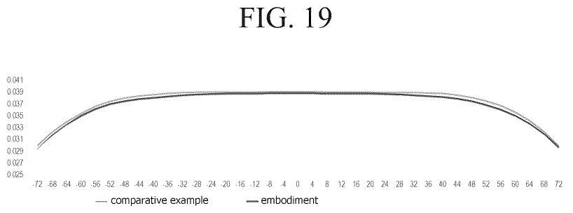

FIG. 19 is a view illustrating the results of simulating light output efficiency of an example and a comparative example according to one or more embodiments of the present disclosure.

FIG. 19 illustrates the results of simulating the light output efficiency of the embodiment in which the third optical layer 143 is formed on the first optical layer 141 and the comparative example in which only the first optical layer 141 is formed, and it can be seen that there is little difference therebetween.

In the structures of the embodiments presented herein, when the fine metal particles are diffused by 0%, the light output efficiency is reduced by about 3.7% compared to the comparative example, and when the fine metal particles are diffused by 50%, the light output efficiency is reduced by about 0.4% compared to the comparative example.

Accordingly, there is little difference between the structures of the embodiments presented herein and the structure of the comparative example in terms of light output efficiency, but in the structures of the embodiments presented herein, fine metal particles are reduced or prevented from being diffused upward, making it easy to form a common electrode.

According to one or more embodiments of the present disclosure, the display apparatus may be applied to mobile devices, video phones, smart watches, watch phones, wearable device, foldable device, rollable device, bendable device, flexible device, curved device, sliding device, variable device, electronic organizer, electronic books, portable multimedia players (PMPs), personal digital assistants (PDAs), MP3 players, mobile medical devices, desktop PCs, laptop PCs, netbook computers, workstations, navigations, vehicle navigations, vehicle display devices, vehicle devices, theater devices, theater display devices, televisions, wallpaper devices, signage devices, game devices, laptops, monitors, cameras, camcorders, and home appliances, etc. Additionally, the display apparatus according to one or more embodiments of the present disclosure may be applied to organic light emitting lighting devices or inorganic light emitting lighting devices.

According to one or more embodiments of the present disclosure, a display apparatus may be described as follows.

According to one or more embodiments of the present disclosure, a display panel may include a substrate; an insulating layer disposed above the substrate; a bank pattern disposed on the insulating layer; a first electrode disposed on the bank pattern; a contact electrode disposed on the insulating layer and spaced apart from the bank pattern; a light-emitting element disposed above the first electrode; a first optical layer surrounding the light-emitting element and made of an organic insulating material including metal particles; a second optical layer formed above the contact electrode; and a third optical layer formed on the first optical layer.

The third optical layer may be formed to have a thickness in a range of 1.0 μm to 1.5 μm.

The third optical layer may be formed so that a top surface is on the same line as or below a top surface of the light-emitting element.

The display panel may further include a solder pattern between the first electrode and the light-emitting element.

The second optical layer includes a contact hole for exposing the contact electrode.

The display panel may further include a second electrode formed on the second optical layer and the third optical layer.

The second optical layer and the third optical layer may be made of a same organic insulating material including no metal particles.

The display panel may further include a buffer layer disposed between the substrate and the insulating layer.

An optical layer is formed in a first area where the first optical layer may be formed and a second area where the contact electrode is formed, and the third optical layer may be formed by exposing the optical layer formed in the first area, by using a half tone mask.

The second optical layer is formed by exposing the optical layer formed in the second area, by using a full tone mask.

The display panel may further include a pixel driving circuit disposed on the substrate.

According to one or more embodiments of the present disclosure, a display apparatus may include a display panel including a plurality of pixels and a pixel driving circuit that drive the plurality of pixels, the display panel may include a substrate; an insulating layer disposed above the substrate; a bank pattern disposed on the insulating layer; a first electrode disposed on the bank pattern; a contact electrode disposed on the insulating layer and spaced apart from the bank pattern; a light-emitting element disposed above the first electrode; a first optical layer surrounding the light-emitting element and made of an organic insulating material including metal particles; a second optical layer formed above the contact electrode; and a third optical layer formed on the first optical layer.

The third optical layer may be formed so that a top surface is on the same line as or below a top surface of the light-emitting element.

The second optical layer may include a contact hole for exposing the contact electrode.

The display apparatus may further include a second electrode formed on the second optical layer and the third optical layer.

The second optical layer and the third optical layer may be made of a same organic insulating material.

An optical layer is formed in a first area where the first optical layer may be formed and a second area where the contact electrode is formed, and the third optical layer may be formed by exposing the optical layer formed in the first area, by using a half tone mask.

The second optical layer is formed by exposing the optical layer formed in the second area, by using a full tone mask.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative and do not limit the present disclosure.

What is claimed is:

1. A display panel, comprising:
a substrate;
an insulating layer on the substrate;
a first electrode on the insulating layer;
a light-emitting element on the first electrode;
a first optical layer surrounding the light-emitting element, the first optical layer comprising an organic insulating material including a plurality of particles; and
a third optical layer on the first optical layer, the third optical layer surrounding the light-emitting element.

2. The display panel of claim 1, wherein the third optical layer has a thickness in a range of 1.0 μm to 1.5 μm.

3. The display panel of claim 1, wherein a top surface of the third optical layer is aligned with a top surface of the light-emitting element or below the top surface of the light-emitting element.

4. The display panel of claim 1, further comprising:
a solder pattern between the first electrode and the light-emitting element.

5. The display panel of claim 1, wherein the third optical layer includes a material without any particles.

6. The display panel of claim 1, wherein the plurality of particles in the first optical layer are diffused in the first optical layer except at a top surface of the third optical layer.

7. The display panel of claim 1, wherein the plurality of particles comprise a metal element.

8. The display panel of claim 1, further comprising:
a second electrode on the light-emitting element and the third optical layer.

9. The display panel of claim 8, further comprising:
a second optical layer on the insulating layer, the second optical layer adjacent to the first optical layer.

10. The display panel of claim 9, wherein the second electrode extends between the third optical layer and the second optical layer from a top surface of the third optical layer to under the second optical layer.

11. The display panel of claim 10, further comprising:
a contact electrode on the insulating layer and spaced apart from the first electrode, wherein
the second optical layer covers at least a portion of the contact electrode, and
the second electrode extends so that the second electrode is connected to the contact electrode under the second optical layer.

12. The display panel of claim 9, further comprising:
a contact electrode on the insulating layer, the contact electrode spaced apart from the first electrode, wherein
the second optical layer covers at least a portion of the contact electrode, and
the second optical layer includes a contact hole that exposes a part of the contact electrode.

13. The display panel of claim 12, wherein a first portion of the second electrode is on the second optical layer and a second portion of the second electrode is connected to the contact electrode through the contact hole.

14. The display panel of claim 9, wherein the second optical layer and the third optical layer include a same organic insulating material without any particles.

15. The display panel of claim 9, wherein:
a top surface of the second optical layer and a top surface of the second electrode on the third optical layer are coplanar, or
the top surface of the second optical layer and a top surface of the third optical layer are coplanar.

16. The display panel of claim 12, further comprising:
a pixel driving circuit on the substrate and below the insulating layer, wherein
the second electrode is connected to the pixel driving circuit via the contact electrode, and
the first electrode extends under the first optical layer and is connected to the pixel driving circuit through the insulating layer.

17. The display panel of claim 1, further comprising:
a bank pattern on the insulating layer, the bank pattern surrounded by the first optical layer,
wherein the first electrode is on the bank pattern.

18. A display apparatus, comprising:
a substrate;
an insulating layer on the substrate;
a first anode on the insulating layer;
a first light emitting element on the first anode;
a second anode on the insulating layer;
a second light emitting element on the second anode;
a first optical layer between and surrounding the first light emitting element and the second light emitting element, the first optical layer comprising an organic insulating material including a plurality of particles;
a third optical layer on an upper surface of the first optical layer, the third optical layer surrounding the first light emitting element and the second light emitting element;
a cathode on the first light emitting element, the second light emitting element, and the third optical layer; and
a pixel driving circuit connected to the first anode and the second anode, the pixel driving circuit configured to supply one or more voltages to at least one of the first anode and the second anode.

19. The display apparatus of claim 18, wherein the pixel driving circuit is configured to drive the first light emitting element by applying a first anode voltage to the first anode and drive the second light emitting element by applying a second anode voltage to the second anode.

20. The display apparatus of claim 19, further comprising:
a buffer layer on the substrate;
a first connection wiring at least partially on the buffer layer, the first connection wiring electrically connected to the pixel driving circuit by passing through the buffer layer;
a first signal wiring on a portion of the first connection wiring, the first signal wiring electrically connecting the first connection wiring to the first anode;
a second connection wiring at least partially on the buffer layer, the second connection wiring electrically connected to the pixel driving circuit by passing through the buffer layer;
a second signal wiring on a portion of the second connection wiring, the second signal wiring electrically connecting the second connection wiring to the second anode, wherein
the pixel driving circuit applies the first anode voltage to the first anode through the first connection wiring and the first signal wiring, and
the pixel driving circuit applies the second anode voltage to the second anode through the second connection wiring and the second signal wiring.

21. The display apparatus of claim 20, further comprising:
a third connection wiring at least partially on the buffer layer, the third connection wiring electrically connected to the pixel driving circuit by passing through the buffer layer, wherein
the pixel driving circuit applies a cathode voltage to the first light emitting element and the second light emitting element through the third connection wiring and the cathode.

22. The display apparatus of claim 21, further comprising:
a contact electrode on the substrate, the contact electrode electrically connected to the third connection wiring, and the cathode is electrically connected to the contact electrode.

23. The display apparatus of claim 18, wherein the pixel driving circuit is configured to:
drive one of the first light emitting element and the second light emitting element by applying an anode voltage to one of the first anode and the second anode.

24. The display apparatus of claim 18, wherein the third optical layer includes an organic insulating material without any particles.

25. The display apparatus of claim 18, further comprising:
a second optical layer on the insulating layer, the second optical layer surrounding the first optical layer, and covers a portion of the cathode.

26. The display apparatus of claim 18, wherein a top surface of the third optical layer is coplanar with a top surface of the first light emitting element and a top surface of the second light emitting element or lower than the top surface of the first light-emitting element and the top surface of the second light emitting element.

27. The display apparatus of claim 18, wherein:
an upper surface of the first optical layer is lower than a first upper surface of the first light-emitting element and a second upper surface of the second light-emitting element; and
a lower surface of the third optical layer is lower than the first upper surface of the first light-emitting element and the second upper surface of the second light-emitting element.
